(19) United States
(12) Patent Application Publication
(10) Pub. No.: US 2025/0098180 A1
(43) Pub. Date: Mar. 20, 2025

(54) SEMICONDUCTOR DEVICE AND METHOD FOR MANUFACTURING THE SAME

(71) Applicant: Samsung Electronics Co., Ltd., Suwon-si (KR)

(72) Inventors: Ki Nam KIM, Suwon-si (KR); Dae Won HA, Suwon-si (KR); Dong Guk CHO, Suwon-si (KR)

(21) Appl. No.: 18/829,396

(22) Filed: Sep. 10, 2024

(30) Foreign Application Priority Data
Sep. 18, 2023 (KR) 10-2023-0124078
May 20, 2024 (KR) 10-2024-0065245

(51) Int. Cl. H10B 80/00; H01L 23/00; H01L 25/00; H01L 25/065; H01L 25/18

(52) U.S. Cl. CPC H10B 80/00; H01L 24/08; H01L 24/80; H01L 25/0657; H01L 25/18; H01L 25/50; H01L 2224/08145; H01L 2224/80006; H01L 2224/80895; H01L 2224/80896; H01L 2224/80908; H01L 2924/1431; H01L 2924/1436

(57) ABSTRACT

There is provided a semiconductor device manufactured using a method that reduces a manufacturing time and cost of the semiconductor device. The semiconductor device includes a first semiconductor device module including: a first lower bonding pad; a second lower bonding pad; first upper bonding pads; and a memory cell disposed at a height level higher than a height level of each of the first and second lower bonding pads and lower than a height level of the first upper bonding pads. The semiconductor device further comprises a second semiconductor device module including second bonding pads and a transistor electrically connected to at least one of the second bonding pads; and a third semiconductor device module including third bonding pads. The third pads are spaced apart from the first and second lower bonding pads in a first direction. The first lower bonding pad contacts at least one of the second bonding pads. At least one of the third bonding pads contacts at least one of the first upper bonding pads. The first semiconductor device module includes a bonding pad connection plug directly electrically connecting the first lower bonding pad and at least one of the first upper bonding pads to each other.

### CROSS-REFERENCE TO RELATED APPLICATION

This application claims priority from Korean Patent Application No. 10-2023-0124078 filed on Sep. 18, 2023, and No. 10-2024-0065245 filed on May 20, 2024 in the Korean Intellectual Property Office, and, the contents of each of which in its entirety are herein incorporated by reference.

### BACKGROUND

### Field

The present invention relates to a semiconductor device and a method for manufacturing the semiconductor device.

### Description of Related Art

Due to the development of electronic technology, down-scaling of a semiconductor device has recently progressed rapidly. Thus, there is a demand for high integration and low power consumption of a semiconductor chip. Generally, in semiconductor manufacturing, a continuous manufacturing scheme involves performing all the necessary sequential steps on a substrate continuously until a final product is achieved.

However, as the semiconductor device becomes more highly integrated and, at the same time, process complexity increases, the time and cost spent on product development and production are increasing exponentially.

### SUMMARY

A technical purpose of the present invention is to provide a semiconductor device manufactured using a method that reduces the manufacturing time and cost of the semiconductor device.

Another technical purpose of the present invention is to provide a semiconductor device manufacturing method that may reduce the manufacturing time and cost of the semiconductor device.

Purposes according to the present invention are not limited to the above-mentioned purpose. Other purposes and advantages not explicitly stated may become apparent from the following descriptions and may be better understood through the embodiments of the invention. Further, it will be easily understood that the purposes and advantages according to the present invention may be realized using the means illustrated in the claims and combinations thereof.

According to an aspect of the present invention, there is provided a semiconductor device comprising a first semiconductor device module including: a first lower bonding pad; a second lower bonding pad; first upper bonding pads; and a memory cell disposed at a height level higher than respective levels of the first and second lower bonding pads and lower than a height level of the first upper bonding pads. The semiconductor device further comprises a second semiconductor device module including second bonding pads and a transistor electrically connected to at least one of the second bonding pads; and a third semiconductor device module including third bonding pads. The third pads are spaced apart from the first and second lower bonding pads in a first direction. The first lower bonding pad contacts at least one of the second bonding pads. At least one of the third bonding pads contacts at least one of the first upper bonding pads. The first semiconductor device module includes a bonding pad connection plug directly electrically connecting the first lower bonding pad and at least one of the first upper bonding pads to each other.

According to another aspect of the present invention, there is provided a semiconductor device comprising a first semiconductor device module including: first bonding pads; second lower bonding pads; first upper bonding pads; and a first semiconductor element disposed at a height level higher than respective heigh levels of the first and second bonding pads and lower than a height level of the first upper bonding pads. The semiconductor device further comprises a second semiconductor device module including second bonding pads and a second semiconductor device element; and a third semiconductor device module including third bonding pads. The first upper bonding pads are spaced apart from the first and second lower bonding pads in a first direction. Each first lower bonding pad contacts at least one of the second bonding pads. At least one of the third bonding pads contacts at least one of the first upper bonding pads. One of the first second semiconductor device elements includes a peripheral circuit, and another includes a memory cell.

According to an aspect of the present invention, there is provided a method for fabricating a semiconductor device comprising forming a first semiconductor device module, wherein the first semiconductor device module includes a first lower bonding pad and first upper bonding pads spaced apart from each other in a first direction, a second bonding pad and a memory cell disposed at a height level higher than respective height levels of the first and second bonding pads and lower than a height level of the first upper bonding pads; forming a second semiconductor device module including second bonding pads and a transistor electrically connected to at least one of the second bonding pads; forming a third semiconductor device module including third bonding pads and wiring lines, wherein at least one of the wiring lines is connected to at least one of the first upper bonding pads; connecting at least one of the second bonding pads and the first lower bonding pad to each other to bond the first semiconductor device module and the second semiconductor device module to each other; and connecting the third bonding pads and the first upper bonding pads to each other in a one-to-one manner to bond the first semiconductor device module and the third semiconductor device module to each other. The first semiconductor device module, the second semiconductor device module, and the third semiconductor device module are formed in a parallel manufacturing scheme.

According to an aspect of the present invention, there is provided a method for fabricating a semiconductor device comprising forming a plurality of first semiconductor device modules, wherein the plurality of first semiconductor device modules includes a first option module and a second option module; forming a plurality of second semiconductor device modules; selecting one option module among the first and second option modules as a first selected semiconductor device module; selecting one semiconductor device module among the plurality of second semiconductor device modules as a second selected semiconductor device module; and bonding the first selected semiconductor device module to the second selected semiconductor device module. The plurality of first semiconductor device modules and the plurality of second semiconductor device modules are produced in a parallel manufacturing scheme. The first and second option modules are structurally different from each other, and are produced by different processes. The first and second option modules are configured to perform the same function as each other.

### BRIEF DESCRIPTION OF DRAWINGS

The above and other aspects and features of the present invention will become more apparent by describing in detail embodiments thereof with reference to the attached drawings, in which:

FIG. 1 is an example diagram for illustrating a semiconductor device according to some embodiments;

FIGS. 2 to 5 are diagrams for illustrating a structure of a logic transistor that may be included in a first semiconductor device module in FIG. 1;

FIGS. 6 to 8 are diagrams for illustrating a bonding pad connection relationship within a second semiconductor device module in FIG. 1;

FIGS. 9 to 12 are diagrams for illustrating configurations of a memory cell array and neighboring elements that may be included in the embodiments in FIGS. 6 to 8, respectively;

FIGS. 13 to 16 are diagrams for illustrating configurations of a wiring structure included in a third semiconductor device module in FIG. 1, respectively;

FIG. 17 and FIG. 18 are diagrams for illustrating bonding pad configurations between the first semiconductor device module and the second semiconductor device module, respectively; and

FIGS. 19 to 34 are diagrams for illustrating a semiconductor device manufacturing method according to some embodiments.

### DETAILED DESCRIPTIONS

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present invention.

It should be noted that items described in the singular herein, may be provided in plural, as can be seen in the various figures from the context in which they are described, and such description should be considered applicable to each of the plural, unless context indicates otherwise.

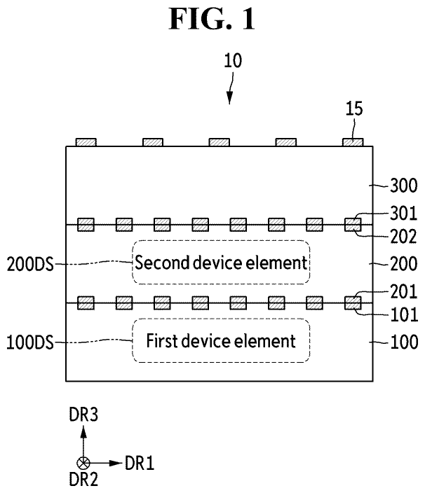

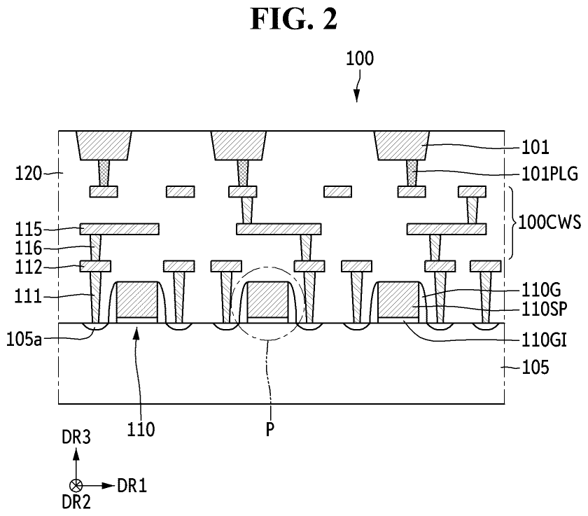

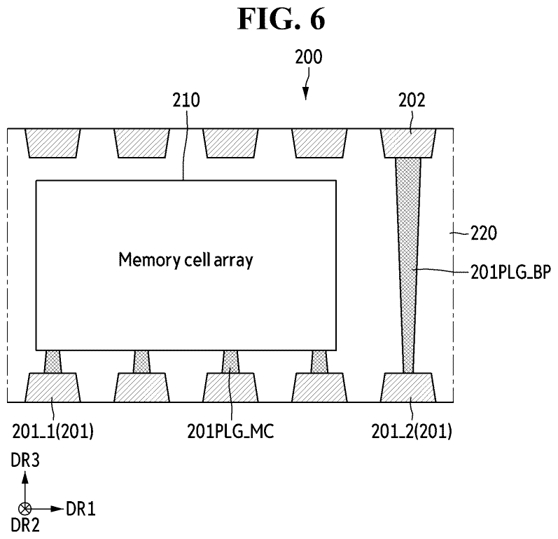

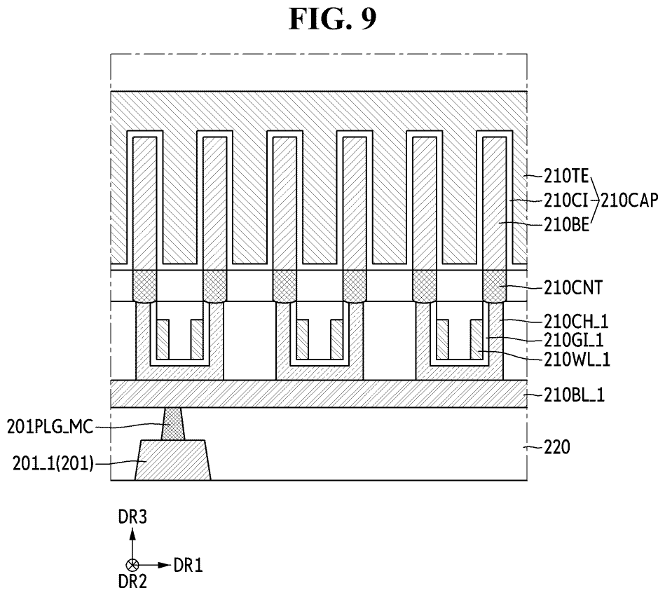

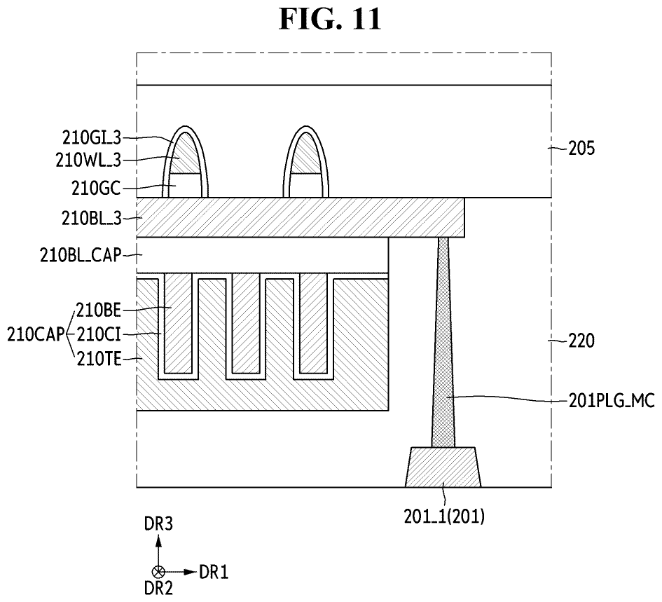

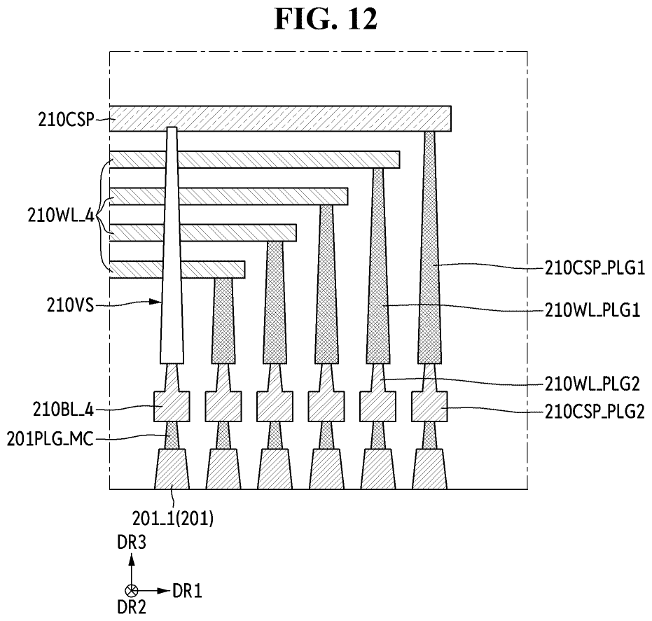

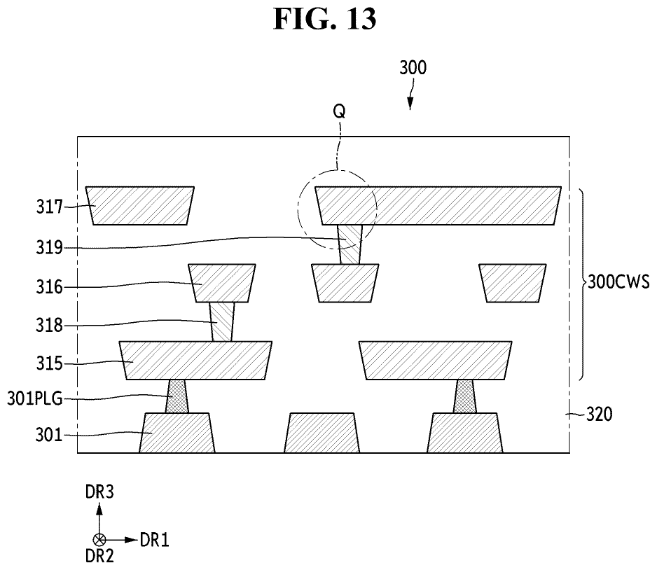

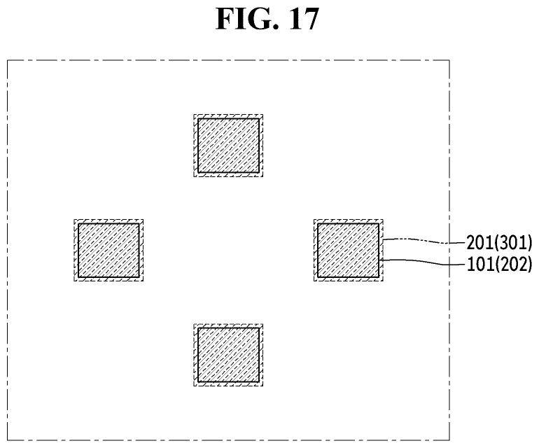

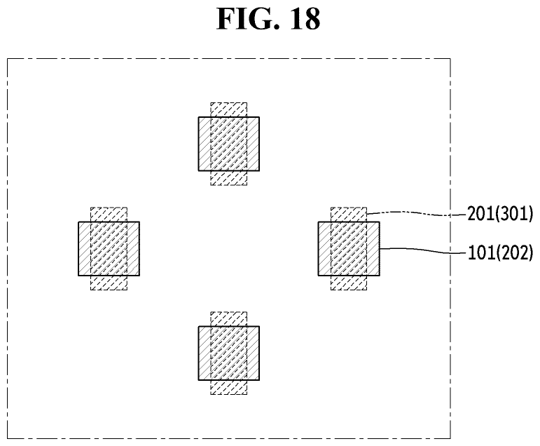

FIG. 1 is an example diagram for illustrating a semiconductor device according to some embodiments. FIGS. 2 to 5 are diagrams for illustrating a structure of a logic transistor that may be included in a first semiconductor device module shown in FIG. 1. FIGS. 6 to 8 are diagrams for illustrating a bonding pad connection relationship within a second semiconductor device module shown in FIG. 1. FIGS. 9 to 12 are diagrams for illustrating configurations of a memory cell array and neighboring elements that may be included in the embodiments shown in FIGS. 6 to 8, respectively. FIGS. 13 to 16 are diagrams for illustrating configurations of a wiring structure included in a third semiconductor device module shown in FIG. 1, respectively. FIG. 17 and FIG. 18 are diagrams for illustrating bonding pad configurations between the first semiconductor device module and the second semiconductor device module, respectively.

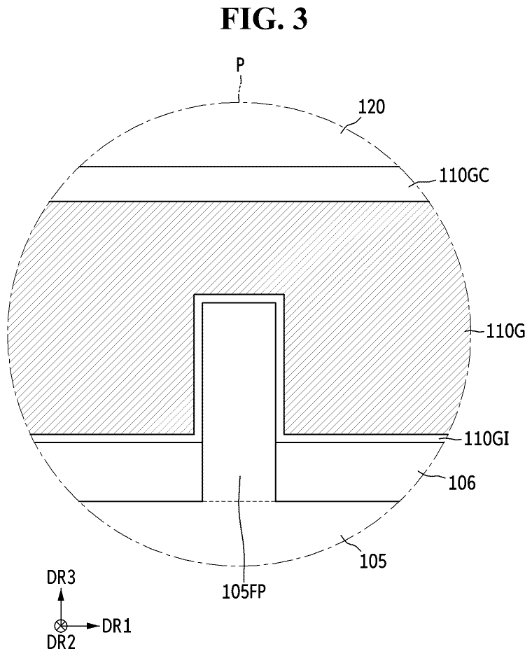

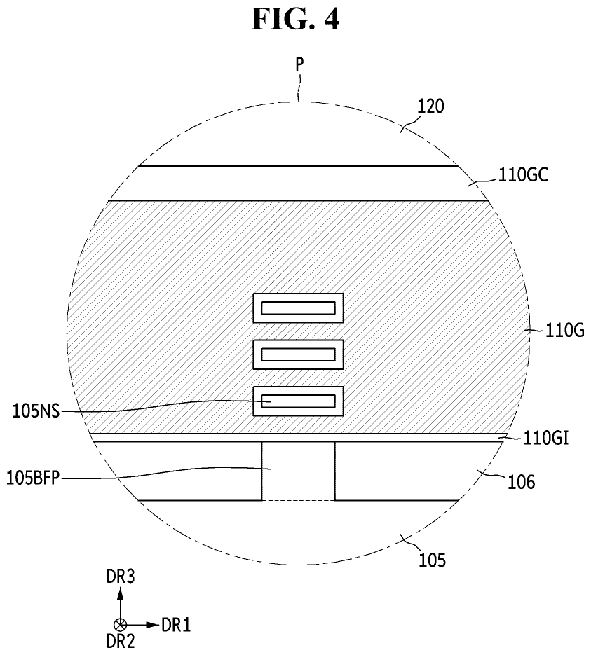

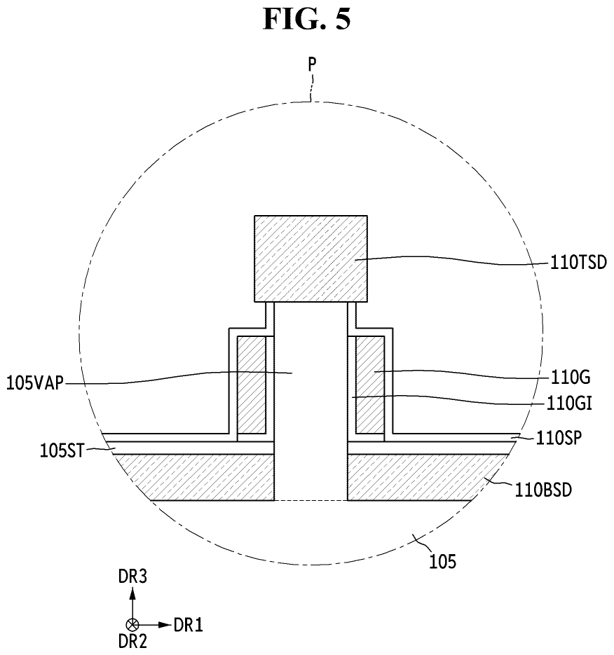

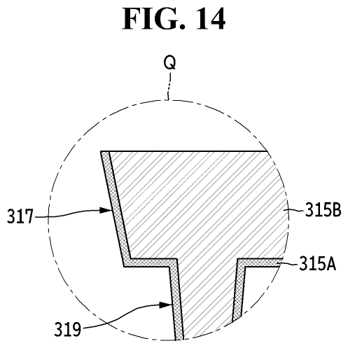

For reference, FIG. 3 and FIG. 4 are diagrams that briefly illustrate modifications of a portion P of FIG. 2, which correspond to a gate portion of a logic transistor, respectively. FIG. 5 is a diagram briefly showing a modified configuration of the logic transistor in FIG. 2. FIG. 14 is a diagram illustrating another configuration of a portion Q in FIG. 13.

Referring to FIGS. 1 to 18, a semiconductor device 10 according to some embodiments may include a first semiconductor device module 100, a second semiconductor device module 200, and a third semiconductor device module 300.

The first semiconductor device module 100, the second semiconductor device module 200, and the third semiconductor device module 300 may be stacked in a third direction DR3. The second semiconductor device module 200 may be disposed between the first semiconductor device module 100 and the third semiconductor device module 300.

The first semiconductor device module 100, the second semiconductor device module 200, and the third semiconductor device module 300 may be bonded to each other. The first semiconductor device module 100 and the second semiconductor device module 200 may be connected to each other via bonding pads. The second semiconductor device module 200 and the third semiconductor device module 300 may be connected to each other via bonding pads.

The first semiconductor device module 100 may include a first device element 100DS and a first bonding pad 101 (only one of the first bonding pads 101 is labeled). The first bonding pads 101 may be arranged to be spaced apart from each other in a first direction DR1. As shown in FIG. 17 and FIG. 18, the first bonding pads 101 may be arranged to be spaced apart from each other in a second direction DR2 (e.g., to be formed in an array pattern).

As used herein, the first direction DR1 may be perpendicular to the second direction DR2 and the third direction DR3. The second direction DR2 may be perpendicular to the third direction DR3.

The second semiconductor device module 200 may include a second device element 200DS, a second lower bonding pad 201 (only one of the second lower bonding pads 201 is labeled), and a second upper bonding pad 202 (only one of the second upper bonding pads 202 is labeled). The second device element 200DS may be disposed between the second lower bonding pads 201 and the second upper bonding pads 202. For example, each of the second lower bonding pads 201 may be formed at a bottom surface of the second device element 200DS in the third direction DR3, and each of the second upper bonding pads 202 may be formed at a bottom surface of the second device element 200DS in the third direction DR3. The second lower bonding pads 201 may be arranged to be spaced apart from each other in the first direction DR1. The second upper bonding pads 202 may be arranged to be spaced apart from each other in the first direction DR1. Although not shown, the second lower bonding pads 201 may be arranged to be spaced apart from each other in the second direction DR2, and the second upper bonding pads 202 may be arranged to be spaced apart from each other in the second direction DR2 (e.g., to be formed in an array pattern).

Each of the second lower bonding pads 201 may be disposed in a position corresponding to a position of a corresponding one of the first bonding pads 101. For example, the second lower bonding pads 201 may correspond to the first bonding pads 101 in a one-to-one manner.

The second lower bonding pad 201 may be connected to the first bonding pad 101. For example, the second lower bonding pad 201 may be directly connected to the first bonding pad 101. The second lower bonding pad 201 may be in contact with the first bonding pad 101.

The term “contact,” “contacting,” “contacts,” or “in contact with,” as used herein, refers to a direct connection (i.e., touching at the point of contact) unless the context clearly indicates otherwise.

As shown in the embodiment of FIG. 17, in a plan view, a shape of the first bonding pad 101 may be identical to a shape of the second lower bonding pad 201. Assuming that the first bonding pad 101 has a square shape, the second lower bonding pad 201 may have a square shape.

Terms such as “identical,” “same,” “equal,” etc. as used herein when referring to features such as orientation, layout, location, shapes, sizes, compositions, amounts, or other measures do not necessarily mean an exactly identical feature but is intended to encompass nearly identical features including typical variations that may occur resulting from conventional manufacturing processes. The term “substantially” may be used herein to emphasize this meaning.

As shown in the embodiment of FIG. 18, the shape of the first bonding pad 101 may be different from the shape of the second lower bonding pad 201. Assuming that the first bonding pad 101 has a square shape, the second lower bonding pad 201 may have a rectangular shape extending in an elongated manner in one direction (for example, the first direction DR1 or the second direction DR2). In order to secure a bonding margin between the second lower bonding pad 201 and the first bonding pad 101, the second lower bonding pad 201 may have a rectangular shape extending in an elongated manner in one direction, unlike the first bonding pad 101. Unlike what is shown, in order to secure the bonding margin, the first bonding pad 101 may have a rectangular shape extending in an elongated manner in one direction.

In one example, the first device element 100DS may include a logic transistor 110, and the second device element 200DS may include memory cells. In another example, the first device element 100DS may include the memory cell array 210, and the second device element 200DS may include the logic transistor 110. In descriptions set forth below, an example in which the first semiconductor device module 100 includes the logic transistor 110, and the second semiconductor device module 200 includes the memory cell array 210 is described. The memory cell array 210 may be disposed at a height level higher than that of the second lower bonding pads 201 and lower than that of second upper bonding pads 202. The memory cells may be referred to as a semiconductor device element or as a part of a semiconductor device element.

For example, the memory cells may be part of a memory cell array 210 that forms a cell array structure capable of storing data therein. The logic transistor 110 may be part of an integrated circuit including a sensing transistor, a transfer transistor, and/or a driving transistor that are used in operation of the memory cell array. For example, the logic transistor 110 may be part of a logic circuit (e.g., a logic gate, such as a NAND, OR, XOR, NOT (an inverter), NAND, NOR, or an XNOR gate).

In an embodiment, the memory cell array may include neighboring elements that may be included in the embodiments shown in FIGS. 9 to 12. The neighboring elements may be parts of a connection structure between the cell array and elements outside of the memory cell array 210.

The third semiconductor device module 300 may include a third bonding pad 301 and a wiring structure 300CWS. The third semiconductor device module 300 may not include the logic transistor 110 and the memory cell array 210. For example, in some embodiments, the third semiconductor device module 300 does not include any logic transistors or memory cells.

The third bonding pads 301 may be arranged to be spaced apart from each other in the first direction DR1. Although not shown, the third bonding pads 301 may be arranged to be spaced apart from each other in the second direction DR2 (e.g., to be formed in an array pattern).

Each of the second upper bonding pads 202 may be disposed in a position corresponding to a corresponding one of the third bonding pads 301. The second upper bonding pads 202 may correspond to the third bonding pads 301 in a one-to-one manner.

The second upper bonding pad 202 may be connected to the third bonding pad 301. For example, the second upper bonding pad 202 may be directly connected to the third bonding pad 301. The second upper bonding pad 202 may be in contact with the third bonding pad 301.

In one example, as shown in FIG. 17, a shape of the third bonding pad 301 may be identical to a shape of the second upper bonding pad 202. In another example, as shown in FIG. 18, the shape of the third bonding pad 301 may be different from the shape of the second upper bonding pad 202.

A contact pad 15 may be disposed on the third semiconductor device module 300. When the third bonding pad 301 is disposed on a first surface of the third semiconductor device module 300, the contact pad 15 may be disposed on a second surface of the third semiconductor device module 300 which is opposite to the first surface of the third semiconductor device module 300 in the third direction DR3. The contact pad 15 may be connected to the wiring structure 300CWS.

The contact pad 15 may electrically connect the semiconductor device 10 to an external device or a mounting substrate. The contact pad 15 may provide an electrical signal or power to the semiconductor device 10. Alternatively, the contact pad 15 may provide an electrical signal from the semiconductor device 10 to the external device. The contact pad 15 may include a conductive material. Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary. The term “consisting of,” on the other hand, indicates that a component is formed only of the element(s) listed.

In an alternative embodiment, contact pads may be disposed on a bottom surface of the first semiconductor device module 100. In yet another alternative embodiment, the third bonding pad 301 may be disposed on the first surface of the third semiconductor device module 300, and an additional bonding pad may be disposed on a bottom surface of the first semiconductor device module 100.

In an alternative embodiment, any one of the second semiconductor device module 200 and the third semiconductor device module 300 may be stacked on the top of the semiconductor device 10 to be the topmost module of the three modules 100-300, and any one of the other two modules may be the bottommost module of the semiconductor device 10. In this case, two adjacent ones of the modules may be connected to each other by bonding pads as described in FIG. 1. The topmost module and/or the bottommost module may have contact pads electrically connecting the semiconductor device 10 to an external device or a mounting substrate.

As shown in FIG. 2, the first semiconductor device module 100 may include logic transistors 110 and the first bonding pads 101 connected to the logic transistors 110. For example, the logic transistors 110 may be electrically connected to the first bonding pads 101. The first semiconductor device module 100 may include a peripheral circuit for the operation of a memory cell array (shown in FIG. 6) such as addressing, data input/output, and control functions. The peripheral circuit may include the logic transistors 110. The peripheral circuit may be referred to as a semiconductor device element or as a part of a semiconductor device element.

As used herein, items described as being “electrically connected” are configured such that an electrical signal can be passed from one item to the other. Therefore, a passive electrically conductive component (e.g., a conductive pattern, a conductive pad, a conductive plug, etc.) physically connected to a passive electrically insulative component (e.g., an insulating film, an insulating pattern, etc.) is not electrically connected to that component. Moreover, components that are “directly electrically connected” form a common electrical node through electrical connections by one or more conductors, such as, for example, wires, pads, internal electrical lines, through vias, etc. As such, directly electrically connected components do not include components electrically connected through active elements, such as transistors or diodes.

The logic transistor 110 may include a peripheral gate electrode 110G, a peripheral gate insulating film 110GI, and a source/drain area 105a. For example, the logic transistor 110 may be a planar transistor.

The peripheral gate electrode 110G and the peripheral gate insulating film 110GI may be disposed on the first substrate 105. The peripheral gate insulating film 110GI may be disposed between the first substrate 105 and the peripheral gate electrode 110G. The source/drain area 105a may be respectively disposed on both opposing sides of the peripheral gate electrode 110G. A peripheral gate spacer 110SP may be disposed on a sidewall of the peripheral gate electrode 110G.

The first substrate 105 may be a silicon substrate, or may include a materials other than silicon such as silicon germanium, indium antimonide, lead telluride compound, indium arsenide, indium phosphide, gallium arsenide, or gallium antimonide. However, the present invention is not limited thereto.

The peripheral gate insulating film 110GI may include a silicon oxide film, a silicon oxynitride film, a high dielectric constant insulating film with a higher dielectric constant than that of the silicon oxide film, or a combination thereof. The high dielectric constant insulating film may include, but the invention is not limited to, at least one of, for example, metal oxide, metal oxynitride, metal silicon oxide, and metal silicon oxynitride. The peripheral gate electrode 110G may include at least one of doped semiconductor material, conductive metal nitride, conductive metal silicon nitride, metal carbonitride, conductive metal silicide, conductive metal oxide, 2D material, and metal. The peripheral gate spacer 110SP may include an insulating material. Although not shown, a peripheral gate capping pattern 110GC as shown in FIG. 3 and FIG. 4 may be further disposed on the peripheral gate electrode 110G.

A peripheral contact plug 111 may be connected to the logic transistor 110. The peripheral contact plug 111 may be connected to the source/drain area 105a. Although not shown, the peripheral contact plug 111 may be connected to the peripheral gate electrode 110G.

A peripheral wiring line 112 may be disposed on the peripheral contact plug 111. The peripheral wiring line 112 is connected to the peripheral contact plug 111. Although the peripheral contact plug 111 and the peripheral wiring line 112 are shown as being embodied as separate films, the present invention is not limited thereto. The peripheral contact plug 111 and the peripheral wiring line 112 may be formed integrally without any boundary there between. Each of the peripheral contact plug 111 and the peripheral wiring line 112 may include a conductive material.

The peripheral wiring structure 100CWS may be disposed between the first bonding pad 101 and the peripheral wiring line 112. The peripheral wiring structure 100CWS may connect the first bonding pad 101 and peripheral wiring line 112 to each other. The peripheral wiring structure 100CWS may include a peripheral connection wiring 115 and a peripheral connection via 116. The peripheral wiring structure 100CWS is shown as including the peripheral connection wirings 115 respectively disposed at a plurality of metal levels. However, this is only for convenience of illustration, and the present invention is not limited thereto. Each of the peripheral connection wiring 115 and the peripheral connection via 116 may include a conductive material.

A first bonding pad plug 101PLG may be disposed between the first bonding pad 101 and the peripheral wiring structure 100CWS. The first bonding pad plug 101PLG may connect the first bonding pad 101 and the peripheral wiring structure 100CWS to each other. The first bonding pad plug 101PLG may include a conductive material.

Unlike what is shown, the first bonding pad 101 may be connected to the peripheral wiring line 112 without the peripheral wiring structure 100CWS. The first bonding pad plug 101PLG may be connected to the peripheral wiring line 112.

As it moves away from the logic transistor 110, a width in the first direction DR1 of the first bonding pad 101 may increase. Although not shown, as it moves away from the logic transistor 110, a width in the second direction DR2 of the first bonding pad 101 may increase.

The first bonding pad 101 may include a conductive material. For example, the first bonding pad 101 may include copper (Cu). However, the present invention is not limited thereto.

A first module insulating film 120 may be disposed on the first substrate 105. The peripheral contact plug 111, the peripheral wiring line 112, the peripheral wiring structure 100CWS, the first bonding pad plug 101PLG, and the first bonding pad 101 may be disposed within the first module insulating film 120.

The first module insulating film 120 may include an insulating material. The first module insulating film 120 is shown as a single film. However, this is only for convenience of illustration, and the present invention is not limited thereto.

The logic transistor 110 in FIG. 2 may be a fin-type transistor (FinFET) including a fin-shaped channel area as shown in FIG. 3.

A fin-shaped pattern 105FP may protrude from the first substrate 105 in the third direction DR3. The fin-shaped pattern 105FP may include a semiconductor material. A field insulating film 106 may be disposed on the first substrate 105. The field insulating film 106 may cover a portion of a sidewall of the fin-shaped pattern 105FP.

The peripheral gate insulating film 110GI may extend along the sidewall and a bottom surface of the fin-shaped pattern 105FP that protrudes from the field insulating film 106 and an upper surface of the field insulating film 106. The peripheral gate electrode 110G may be disposed on the peripheral gate insulating film 110GI. A peripheral gate capping pattern 110GC may be disposed on the peripheral gate electrode 110G. The peripheral gate capping pattern 110GC may include an insulating material.

The logic transistor 110 in FIG. 2 may be a transistor with a nanowire or nanosheet as a channel area, for example, a multi-bridge channel field effect transistor (MBCFET™) as shown in FIG. 4.

A lower pattern 105BFP may protrude from the first substrate 105 in the third direction DR3. A sheet pattern 105NS may be disposed on the lower pattern 105BFP. The sheet pattern 105NS may be spaced apart from the lower pattern 105BFP in the third direction DR3. The sheet pattern 105NS may include a semiconductor material. Although three sheet patterns 105NS are shown as being arranged in the third direction DR3 on the lower pattern 105BFP, the present invention is not limited thereto. The field insulating film 106 covers at least a portion of a sidewall of the lower pattern 105BFP. The field insulating film 106 does not cover an upper surface of the lower pattern 105BFP.

The peripheral gate insulating film 110GI may extend along the upper surface of the lower pattern 105BFP and the upper surface of the field insulating film 106. In a cross-sectional view, the peripheral gate insulating film 110GI may extend along a perimeter of the sheet pattern 105NS. The peripheral gate electrode 110G may be disposed on the lower pattern 105BFP. The peripheral gate electrode 110G may surround each of the sheet patterns 105NS.

The logic transistor 110 in FIG. 2 may be vertical transistor (Vertical FET) with its channel embodied as a vertical pattern protruding from the first substrate 105 as shown in FIG. 5.

A vertical channel pattern 105VAP may protrude from the first substrate 105 in the third direction DR3. The vertical channel pattern 105VAP may include a semiconductor material. A lower source/drain pattern 110BSD may be disposed on the first substrate 105. The lower source/drain pattern 110BSD may cover a portion of a sidewall of the vertical channel pattern 105VAP. The vertical channel pattern 105VAP protrudes in the third direction DR3 beyond the lower source/drain pattern 110BSD. In one example, the lower source/drain pattern 110BSD may be a semiconductor epitaxial pattern formed by epitaxial growth. In another example, the lower source/drain pattern 110BSD may be an impurity area in which impurities are doped into a semiconductor material.

A field isolation pattern 105ST may be disposed on the lower source/drain pattern 110BSD. The field isolation pattern 105ST may cover an upper surface of the lower source/drain pattern 110BSD. The field isolation pattern 105ST may include an insulating material.

The peripheral gate electrode 110G may be disposed on the field isolation pattern 105ST. The peripheral gate electrode 110G may be disposed on the lower source/drain pattern 110BSD. The peripheral gate electrode 110G is spaced apart from the lower source/drain pattern 110BSD in the third direction DR3. A peripheral gate insulating film 110GI may be disposed on the field isolation pattern 105ST. The peripheral gate insulating film 110GI may be disposed between the vertical channel pattern 105VAP and the peripheral gate electrode 110G and between the lower source/drain pattern 110BSD and the peripheral gate electrode 110G.

An upper source/drain pattern 110TSD may be disposed on the vertical channel pattern 105VAP. The upper source/drain pattern 110TSD may be spaced apart from the lower source/drain pattern 110BSD in the third direction DR3. The upper source/drain pattern 110TSD may be a semiconductor epitaxial pattern formed by epitaxial growth.

The peripheral gate spacer 110SP may be disposed on the field isolation pattern 105ST. The peripheral gate spacer 110SP may cover the peripheral gate electrode 110G and the vertical channel pattern 105VAP. The upper source/drain pattern 110TSD is shown as being disposed on top of the peripheral gate spacer 110SP. However, the present invention is not limited thereto. Unlike what is shown, the peripheral gate spacer 110SP may cover a sidewall of the upper source/drain pattern 110TSD.

FIGS. 2-5 therefore depict different types of transistors that may be formed in different types of first semiconductor device modules 100. For example, one type of first semiconductor device module 100 may be a module in which all of its transistors are planar type transistors, another type of first semiconductor device module 100 may be a module in which all of its transistors are FinFET type transistors, etc. Some types of first semiconductor device modules 100 may include a combination of two or more different types of transistors.

In FIGS. 6 to 8, the second semiconductor device module 200 may include second lower bonding pads 201, second upper bonding pads 202, memory cell array 210, bonding pad connection plugs 201PLG_BP, and memory cell connection plugs 201PLG_MC.

The memory cell array 210 may be disposed between the second lower bonding pads 201 and the second upper bonding pads 202. The bonding pad connection plugs 201PLG_BP may connect the second lower bonding pads 201 and the second upper bonding pads 202 to each other. The memory cell connection plugs 201PLG_MC may connect memory cells of the memory cell array 210 and the second lower bonding pads 201, in a one-to-one manner.

As it moves away from the second upper bonding pad 202, a width of the second lower bonding pad 201 may increase. As it moves away from the second lower bonding pad 201, a width of the second upper bonding pad 202 may increase.

The second lower bonding pads 201 may include cell connection bonding pads 201_1 and pad connection bonding pads 201_2.

The second lower bonding pads 201 may be connected to the memory cell array 210. For example, some cell connection bonding pads 201_1 may be connected to the memory cell array 210. The cell connection bonding pads 201_1 may be connected to bit-lines 210BL_1, 210BL_2, 210BL_3, or 210BL_4 (shown in FIGS. 9, 10, 11, and 12) included in the memory cell array. Some cell connection bonding pads 201_1 may be connected to word-lines 210WL_1, 210WL_2, 210WL_3, or 210WL_4 (shown in FIGS. 9, 10, 11, and 12) included in the memory cell array. Each memory cell connection plug 201PLG_MC may connect a memory cell and a cell connection bonding pad 201_1 to each other.

The pad connection bonding pads 201_2 may be connected to the second upper bonding pads 202. Each bonding pad connection plugs 201PLG_BP may connect a pad connection bonding pad 201_2 and a second upper bonding pad 202 to each other.

Within the second semiconductor device module 200, the pad connection bonding pads 201_2 may not be connected to the memory cell array 210. For example, within the second semiconductor device module 200, the pad connection bonding pads 201_2 may not be connected to any bit-lines included in the memory cell array. Within the second semiconductor device module 200, the pad connection bonding pads 201_2 may not be connected to the any word-lines included in the memory cell array. The pad connection bonding pads 201_2 and bonding pad connection plugs 201PLG_BP may connect logic transistors 110 of the first semiconductor device module 100 and the wiring structure 300CWS of the third semiconductor device module 300 to each other.

The pad connection bonding pads 201_2 and bonding pad connection plugs 201PLG_BP may not be electrically connected to the memory cell array 210 through any elements or items within the second semiconductor device module 200 such that each of the pad connection bonding pad 201_2 and bonding pad connection plug 201PLG_BP may form different electrical nodes and not be electrically connected to each other (at least not directly such that they would form a single electrical node within the second semiconductor device module 200). Within the second semiconductor device module 200, each of the pad connection bonding pads 201_2 and bonding pad connection plugs 201PLG_BP may be electrically isolated from, and may carry different electrical signals from, the elements of the memory cell array. For example, the pad connection bonding pads 201_2 and bonding pad connection plugs 201PLG_BP may not be electrically connected to any bit-lines or word-lines at least within the second semiconductor device module 200.

In some embodiments, the pad connection bonding pads 201_2 and bonding pad connection plugs 201PLG_BP may not be electrically connected to the memory cell array 210 through any elements or items within the second semiconductor device module 200. In some embodiments, the pad connection bonding pads 201_2 and bonding pad connection plugs 201PLG_BP may be electrically connected through the first semiconductor device module 100 and/or the third semiconductor device module 300. The bonding pad connection plug 201PLG_BP may directly electrically connect the pad connection bonding pad 201_2 and the second upper bonding pad 202 to each other, and may be directly physically connected to each of the pad connection bonding pad 201_2 and the second upper bonding pad 202.

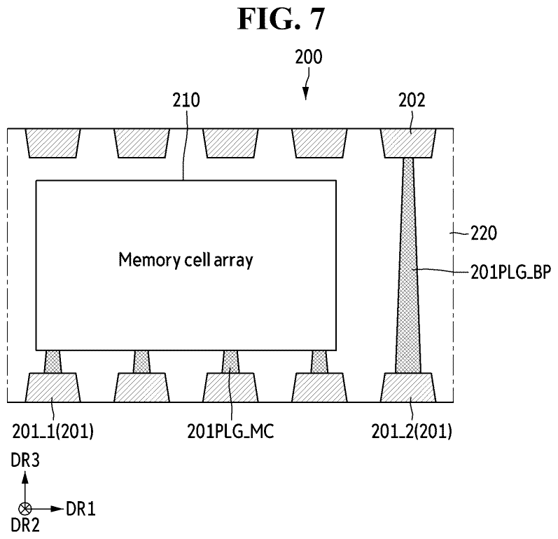

In FIG. 6 and FIG. 7, each pair of a pad connection bonding pad 201_2 and a second upper bonding pad 202 may be connected to each other via a single bonding pad connection plug 201PLG_BP extending in the third direction DR3. In FIG. 6, a width of the bonding pad connection plug 201PLG_BP may decrease as it moves away from the second upper bonding pad 202. In FIG. 7, a width of the bonding pad connection plug 201PLG_BP may decrease as it moves away from the second lower bonding pad 201.

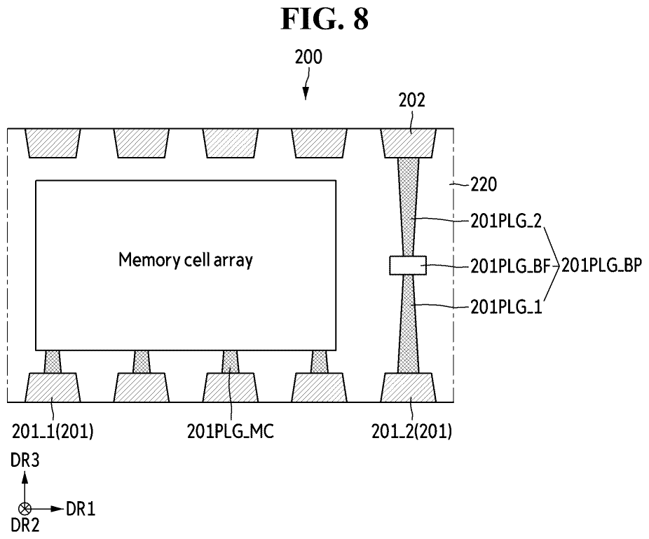

In FIG. 8, each bonding pad connection plug 201PLG_BP may include a lower bonding connection plug 201PLG_1, an upper bonding connection plug 201PLG_2, and a buffer conductive pattern 201PLG_BF. The buffer conductive pattern 201PLG_BF may be disposed between the lower bonding connection plug 201PLG_1 and the upper bonding connection plug 201PLG_2.

The lower bonding connection plug 201PLG_1 is connected to the pad connection bonding pad 201_2. A width of the lower bonding connection plug 201PLG_1 may decrease as it moves away from the pad connection bonding pad 201_2. The upper bonding connection plug 201PLG_2 is connected to the second upper bonding pad 202. A width of the upper bonding connection plug 201PLG_2 may decrease as it moves away from the second upper bonding pad 202.

The second lower bonding pads 201, the second upper bonding pads 202, the memory cell array 210, the bonding pad connection plugs 201PLG_BP, and the memory cell connection plugs 201PLG_MC may be disposed in a second module insulating film 220.

FIGS. 6-8 therefore depict different types of plugs that may be formed in different types of second semiconductor device modules 200. For example, one type of second semiconductor device module 200 may be a module that includes a plurality of bonding connection plugs 201PLG_BP such as shown in FIG. 6, another type of second semiconductor device module 200 may be a module that includes a plurality of bonding connection plugs 201PLG_BP such as shown in FIG. 7, etc. Some types of second semiconductor device modules 200 may include a combination of two or more different types of transistors, or a combination of two or more different types of memory cell arrays.

FIGS. 9 to 12 are diagrams for illustrating different types of a memory cell array and neighboring elements that may be included in the embodiments shown in FIGS. 6 to 8.

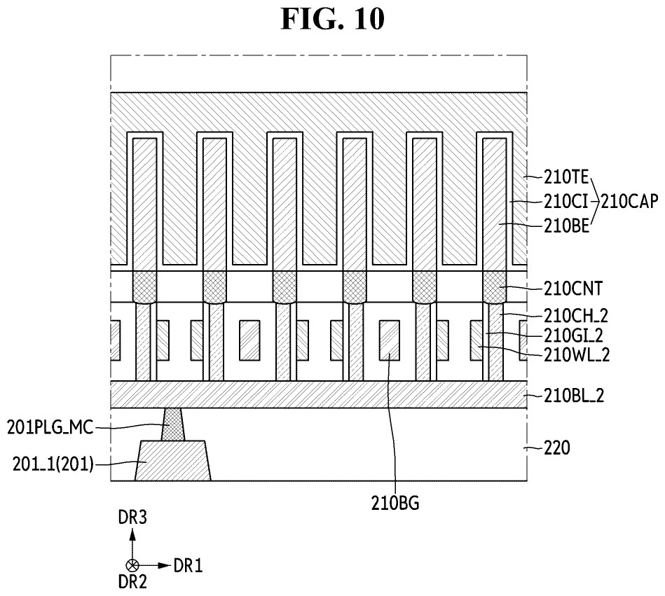

As shown in the embodiments of FIGS. 6 to 9, the memory cell array 210 may include the first bit-line 210BL_1, the first word-line 210WL_1, a first channel pattern 210CH_1, and a data storage pattern 210CAP (only one of the memory cells is labeled). Although not shown, a back gate electrode (210BG in FIG. 10) may be further disposed between adjacent first channel patterns 210CH_1.

The first bit-line 210BL_1 may extend in the first direction DR1. The first bit-line 210BL_1 may be connected to the cell connection bonding pads 201_1 (only one shown in FIG. 9 for simplicity). A plurality of first channel patterns 210CH_1 may be disposed on the first bit-line 210BL_1. The first channel patterns 210CH_1 may be arranged to be spaced apart from each other in the first direction DR1 (e.g., to be formed in an array pattern).

In some embodiments, a plurality of the first bit-lines 210BL_1 may be included in the memory cell array. The plurality of the first bit-lines 210BL_1 may be connected to the cell connection bonding pads 201_1. The plurality of first channel patterns 210CH_1 may be connected to the plurality of the first bit-lines 210BL_1, respectively.

The first word-line 210WL_1 may extend in the second direction DR2. Although not shown, the first word-line 210WL_1 may be connected to the cell connection bonding pad 201_1. The first word-line 210WL_1 may be disposed on the first channel pattern 210CH_1. The first cell gate insulating film 210GI_1 may be disposed between the first word-line 210WL_1 and the first channel pattern 210CH_1. A contact pattern 210CNT may be disposed on the first channel pattern 210CH_1. The contact pattern 210CNT is electrically connected to the first channel pattern 210CH_1.

Each of the first bit-line 210BL_1, the first word-line 210WL_1 and the contact pattern 210CNT may include at least one of doped semiconductor material, conductive metal nitride, conductive metal silicon nitride, metal carbonitride, conductive metal silicide, conductive metal oxide, 2D material and metal. The first cell gate insulating film 210GI_1 may include a silicon oxide film, a silicon oxynitride film, a high dielectric constant insulating film with a higher dielectric constant than that of the silicon oxide film, or a combination thereof.

The first channel pattern 210CH_1 may include an oxide semiconductor material. The first channel pattern 210CH_1 may include, for example, metal oxide. In one example, the first channel pattern 210CH_1 may be embodied as an amorphous metal oxide film. In another example, the first channel pattern 210CH_1 may be embodied as a polycrystalline metal oxide film. In still another example, the first channel pattern 210CH_1 may be embodied as a combination of an amorphous metal oxide film and a polycrystalline metal oxide film. In yet another example, the first channel pattern 210CH_1 may be embodied as a c-axis aligned crystalline (CAAC) metal oxide film.

Each of the data storage patterns 210CAP may be disposed on each of the contact patterns 210CNT. The data storage pattern 210CAP may be electrically connected to the first channel pattern 210CH_1. In one example, the data storage pattern 210CAP may act as a capacitor. The data storage pattern 210CAP may include a storage electrode 210BE, a plate electrode 210TE, and a capacitor dielectric film 210CI interposed between the storage electrode 210BE and the plate electrode 210TE. Each of the storage electrode 210BE and the plate electrode 210TE may include at least one of, for example, a conductive semiconductor material, a conductive metal nitride, a conductive metal silicon nitride, a metal carbonitride, a conductive metal silicide, a conductive metal oxide, and a metal. The capacitor dielectric film 210CI may include at least one of a ferroelectric material, an antiferroelectric material, and a paraelectric material. For example, the capacitor dielectric film 210CI may include one of a ferroelectric material, an antiferroelectric material, a paraelectric material, a combination of a ferroelectric material and an antiferroelectric material, a combination of a ferroelectric material and a paraelectric material, a combination of a paraelectric material and an antiferroelectric material, and a combination of a ferroelectric material, an antiferroelectric material, and a paraelectric material.

Alternatively, each of the data storage patterns 210CAP may be embodied as a variable resistance pattern that may be switched to between two resistance states under an electrical pulse applied to a memory element. For example, each of the data storage patterns 210CAP may include a phase-change material having a crystal state varying depending on an amount of current, perovskite compounds, transition metal oxides, magnetic materials, ferromagnetic materials, or antiferromagnetic materials.

As shown in the embodiments of FIGS. 6 to 8 and FIG. 10, the memory cell array 210 may include the second bit-line 210BL_2, the second word-line 210WL_2, a second channel pattern 210CH_2, and a data storage pattern 210CAP. The memory cell array 210 may include the back gate electrode 210BG. Differences thereof from what have been described with reference to FIG. 9 will be mainly described.

The back gate electrode 210BG may be disposed on the second bit-line 210BL_2. Two second channel patterns 210CH_2 and two second word-lines 210WL_2 may be disposed between back gate electrodes 210BG adjacent to each other in the first direction DR1. In a cross-sectional view, one second channel pattern 210CH_2 may be disposed between the back gate electrode 210BG and the second word-line 210WL_2.

The back gate electrode 210BG may include at least one of a doped semiconductor material, conductive metal nitride, conductive metal silicon nitride, metal carbonitride, conductive metal silicide, conductive metal oxide, 2D material, and metal. The second channel pattern 210CH_2 may be made of a single crystal semiconductor material. For example, the second channel pattern 210CH_2 may be made of single crystal silicon.

Unlike what is shown, the memory cell array 210 may not include any back gate electrode.

As shown in the embodiments of FIGS. 6 to 8 and FIG. 11, the memory cell array 210 may include a second substrate 205, the third bit-line 210BL_3, the third word-line 210WL_3, and the data storage pattern 210CAP. The following description will mainly address the differences from what has been previously detailed with reference to FIGS. 9 and 10.

The third bit-line 210BL_3 may extend in the first direction DR1 and be disposed on the second substrate 205. The third bit-line 210BL_3 may be connected to the cell connection bonding pad 201_1 at an end of the third bit-line 210BL_3.

The third word-line 210WL_3 may extend in the second direction DR2 while being disposed within the second substrate 205. A cell gate capping pattern 210GC may extend along the third word-line 210WL_3. The cell gate capping pattern 210GC may be disposed between the third bit-line 210BL_3 and the third word-line 210WL_3. The cell gate capping pattern 210GC may be disposed within the second substrate 205. A third cell gate insulating film 210GI_3 may be disposed between the second substrate 205 and the third word-line 210WL_3 and between the second substrate 205 and the cell gate capping pattern 210GC.

A bit-line capping pattern 210BL_CAP may be disposed between the third bit-line 210BL_3 and the data storage pattern 210CAP. The bit-line capping pattern 210BL_CAP may extend in the first direction DR1 and along the third bit-line 210BL_3. Each of the bit-line capping pattern 210BL_CAP and the cell gate capping pattern 210GC may include an insulating material.

As shown in the embodiments of n FIGS. 6 to 8 and FIG. 12, the memory cell array 210 may include a common source line 210CSP, a plurality of fourth word-lines 210WL_4, a memory channel structure 210VS, and the fourth bit-line 210BL_4. The following description will mainly address the differences from what has been previously detailed with reference to FIGS. 9, 10 and 11.

The common source line 210CSP may have a plate shape. The common source line 210CSP may include a conductive material. The plurality of fourth word-lines 210WL_4 may be arranged in the third direction DR3 while being disposed under the common source line 210CSP. The plurality of fourth word-lines 210WL_4 may be arranged in a stepwise manner. Each fourth word-line 210WL_4 may extend in the first direction DR1.

The memory channel structure 210VS may extend through the plurality of fourth word-lines 210WL_4. The memory channel structure 210VS may include a channel area and a charge storage area. The channel area of the memory channel structure 210VS may be electrically connected to the common source line 210CSP. The fourth bit-lines 210BL_4 may be disposed on the memory channel structure 210VS. The fourth bit-lines 210BL_4 may extend in the second direction DR2. The fourth bit-lines 210BL_4 may be electrically connected to the channel area of the memory channel structure 210VS. The fourth bit-lines 210BL_4 may be connected to the cell connection bonding pad 201_1.

Each fourth word-line 210WL_4 may be connected to the cell connection bonding pad 201_1. For example, each fourth word-line 210WL_4 may be connected to the cell connection bonding pad 201_1 via a first word-line plug 210WL_PLG1 and a second word-line plug 210WL_PLG2.

The common source line 210CSP may be connected to the cell connection bonding pad 201_1. For example, the common source line 210CSP may be connected to the cell connection bonding pad 201_1 via a first source line plug 210CSP_PLG1 and a second source line plug 210CSP_PLG2.

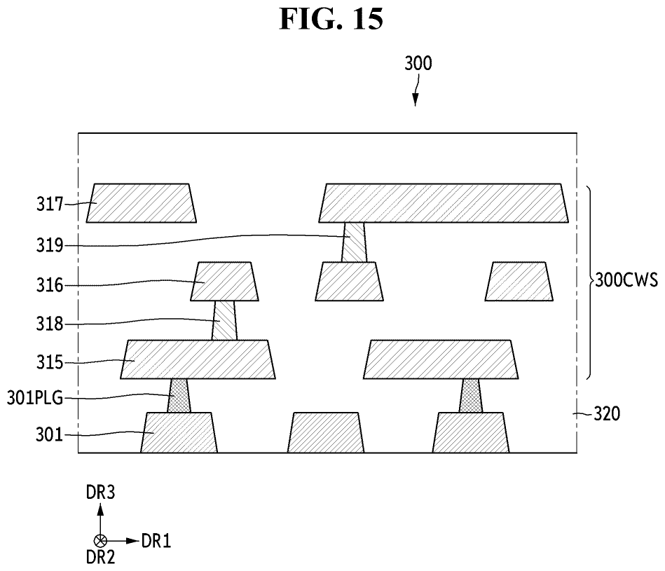

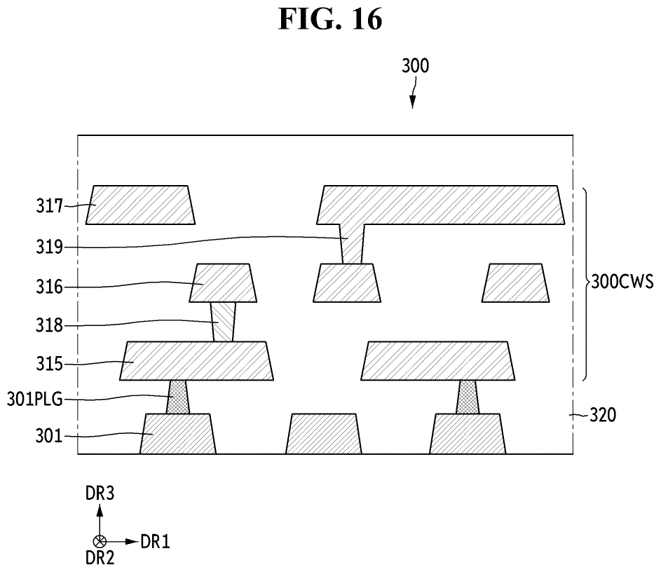

FIGS. 13 to 16 are diagrams for illustrating different types of a wiring structure included in a third semiconductor device module in FIG. 1. As shown in the embodiments of FIG. 13, FIG. 15, and FIG. 16, the third semiconductor device module 300 may include the wiring structure 300CWS and the third bonding pad 301 connected to the wiring structure 300CWS.

The wiring structure 300CWS may include a plurality of wiring connection lines 315, 316, and 317 and wiring connection vias 318 and 319. The wiring connection lines 315, 316, and 317 may include the first wiring connection line 315, the second wiring connection line 316, and the third wiring connection line 317 spaced apart from each other in the third direction DR3. The first wiring connection line 315 may be the wiring connection line closest to the third bonding pad 301 in the third direction DR3. The third wiring connection line 317 may be the wiring connection line furthest from the third bonding pad 301 in the third direction DR3.

The wiring connection vias 318 and 319 may include the first wiring connection via 318 and the second wiring connection via 319. The first wiring connection via 318 may connect the first wiring connection line 315 and the second wiring connection line 316 to each other. The second wiring connection via 319 may connect the second wiring connection line 316 and the third wiring connection line 317 to each other.

The wiring structure 300CWS is shown as including the wiring connection lines 315, 316, and 317 arranged at three different metal levels. However, this is only for convenience of illustration, and the present invention is not limited thereto. In one example, the wiring structure 300CWS may include wiring connection lines respectively disposed at two different metal levels. In another example, the wiring structure 300CWS may include wiring connection lines respectively disposed at four different metal levels.

A third bonding pad plug 301PLG may be disposed between the wiring structure 300CWS and the third bonding pad 301. The third bonding pad plug 301PLG may connect the wiring structure 300CWS and the third bonding pad 301 to each other. The third bonding pad plug 301PLG may be connected to the first wiring connection line 315.

Each of the wiring connection lines 315, 316, and 317 and the wiring connection vias 318 and 319 may contain a conductive material.

As shown in the embodiment of FIG. 14, the third wiring connection line 317 and the second wiring connection via 319 may be formed using a dual damascene scheme. The third wiring connection line 317 and the second wiring connection via 319 may be formed simultaneously. For example, a combination of the third wiring connection line 317 and the second wiring connection via 319 may include a wiring barrier film 315A and a wiring filling film 315B. Each of the third wiring connection line 317 and the second wiring connection via 319 may include a portion of the wiring barrier film 315A and a portion of the wiring filling film 315B.

Unlike what is shown, the third wiring connection line 317 and the second wiring connection via 319 may be formed using a single damascene scheme. Each of the third wiring connection line 317 and the second wiring connection via 319 may be formed in a separate manufacturing process. For example, the second wiring connection via 319 may be formed, and, subsequently, the third wiring connection line 317 may be formed.

The wiring structure 300CWS and the third bonding pad 301 may be disposed within a third module insulating film 320.

As shown in the embodiments of FIG. 13, FIG. 15, and FIG. 16, in the cross-sectional view, each of the third bonding pad plug 301PLG and the third bonding pad 301 may have a trapezoidal shape. A width of the third bonding pad plug 301PLG may decrease as the third bonding pad plug 301PLG extends away from the third bonding pad 301.

As shown in the embodiment of FIG. 13, each of the wiring connection lines 315, 316, and 317 may have an inverted trapezoid shape. Each of the wiring connection vias 318 and 319 may have an inverted trapezoidal shape. The first wiring connection line 315 may be formed, and, subsequently, the second wiring connection line 316 and the third wiring connection line 317 may be sequentially formed on the first wiring connection line 315. Subsequently, the third bonding pad plug 301PLG and the third bonding pad 301 connected to the first wiring connection line 315 may be formed.

As shown in the embodiment of FIG. 15, each of the wiring connection lines 315, 316, and 317 may have a trapezoidal shape. Each of the wiring connection vias 318 and 319 may have a trapezoidal shape. The third wiring connection line 317 may be formed, and, subsequently, the second wiring connection line 316 may be formed on the third wiring connection line 317. Subsequently, the first wiring connection line 315 may be formed on the second wiring connection line 316. Subsequently, the third bonding pad plug 301PLG and the third bonding pad 301 may be formed on the first wiring connection line 315.

As shown in the embodiment of FIG. 16, each of the wiring connection lines 315, 316, and 317 may have a trapezoidal shape, and each of the wiring connection vias 318 and 319 may have an inverted trapezoidal shape. The first wiring connection line 315, the second wiring connection line 316, and the third wiring connection line 317 may be formed sequentially, and, subsequently, the third bonding pad plug 301PLG and the third bonding pad 301 may be formed. For example, each of the wiring connection vias 318 and 319 may be formed using the damascene scheme. Each of the wiring connection lines 315, 316, and 317 may be formed using a subtractive etch scheme.

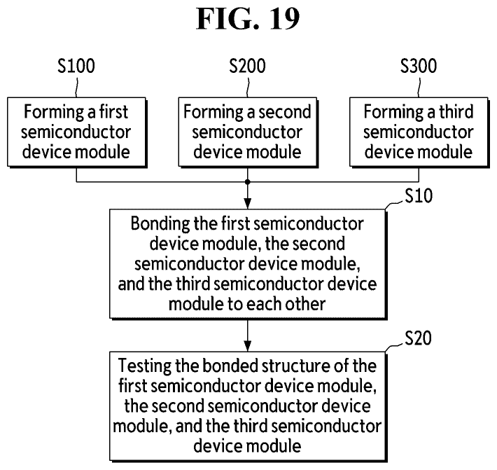

FIGS. 19 to 33 are diagrams for illustrating a semiconductor device manufacturing method according to some embodiments.

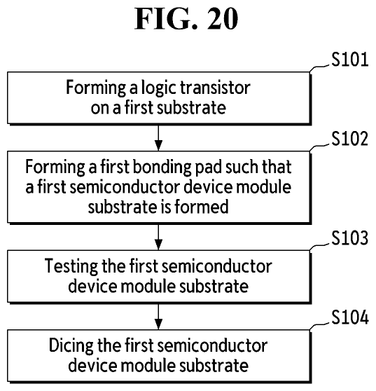

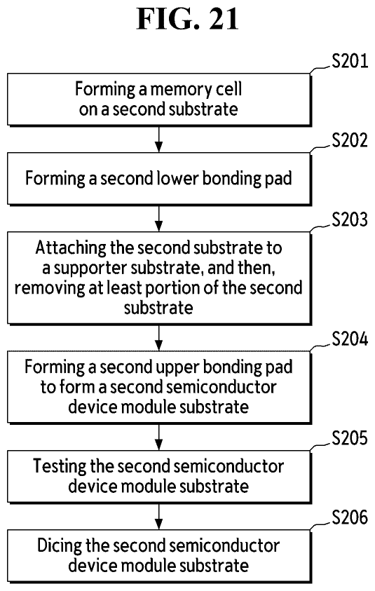

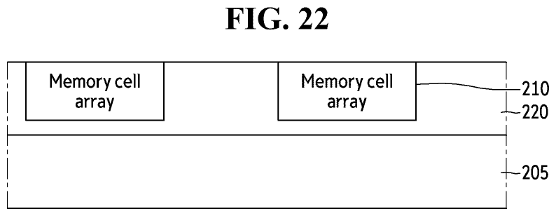

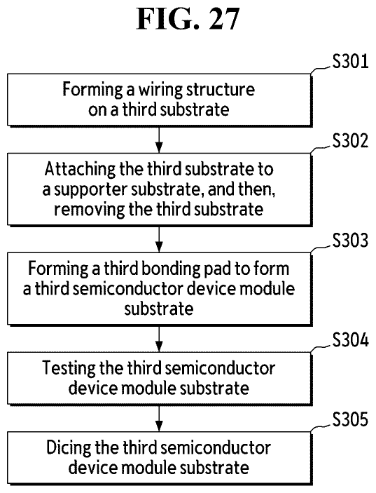

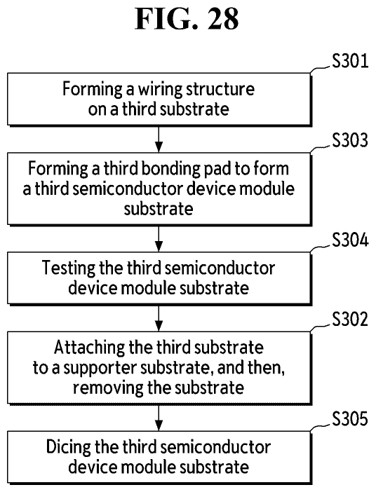

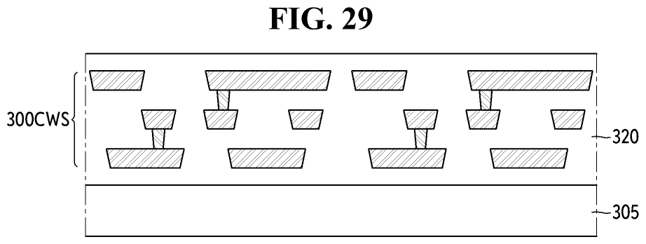

For reference, FIG. 19 is a flowchart for illustrating a semiconductor device manufacturing method according to some embodiments. FIG. 20 is a flowchart for illustrating forming the first semiconductor device module in FIG. 19. FIG. 21 is a flowchart for illustrating forming the second semiconductor device module in FIG. 19. FIGS. 22 to 26 are diagrams for illustrating a process for forming the second semiconductor device module. FIG. 27 and FIG. 28 are flow charts for illustrating forming the third semiconductor device module, respectively. FIG. 29 to FIG. 32 are diagrams for illustrating a process for forming the third semiconductor device module.

In descriptions set forth below, contents duplicate with what have been described above using FIGS. 1 to 18 are briefly described or descriptions thereof are omitted.

Referring to FIG. 19, the first semiconductor device module 100 in FIG. 1 may be formed in S100. The second semiconductor device module 200 in FIG. 1 may be formed in S200. The third semiconductor device module 300 in FIG. 1 may be formed in S300.

The first semiconductor device module 100, the second semiconductor device module 200, and the third semiconductor device module 300 are not formed using a continuous manufacturing process. For example, the first semiconductor device module 100, the second semiconductor device module 200, and the third semiconductor device module 300 may be formed using a parallel manufacturing scheme.

Hereinafter, the parallel manufacturing scheme is described. For example, the first semiconductor device module 100 may be formed in a first fab (i.e., a particular fabrication area, in which semiconductor products are manufactured). The second semiconductor device module 200 may be formed in a second fab. The third semiconductor device module 300 may be formed in a third fab.

In one example, the first to third fabs may be different fabs. In another example, the first fab for producing the first semiconductor device module 100 may be the same as the second fab for producing the second semiconductor device module 200. However, a semiconductor production apparatus that produces the first semiconductor device module 100 may be different from a semiconductor production apparatus that produces the second semiconductor device module 200.

The manufacturing process of the semiconductor device 10 may be divided into three stages, which are sub-manufacturing processes for the first, second and third semiconductor device modules 100, 200 and 300 respectively. A time required to produce the first semiconductor device module 100 (also referred to as a “cycle time”) may be a first sub-production time T1. A time required to produce the second semiconductor device module 200 may be a second sub-production time T2. A time required to produce the third semiconductor device module 300 may be a third sub-production time T3.

When the semiconductor device 10 in FIG. 1 including the first semiconductor device module 100, the second semiconductor device module 200, and the third semiconductor device module 300 is formed in a continuous manufacturing process, a cycle time required to produce the semiconductor device 10 may be a sum of the first, second and third sub-production times T1, T2 and T3. However, when the first semiconductor device module 100, the second semiconductor device module 200, and the third semiconductor device module 300 are formed in a parallel manufacturing scheme, a cycle time required to produce the semiconductor device 10 may not be the total process time (i.e., the sum of the first, second and third sub-production times T1, T2 and T3), but the cycle time may depend on the greatest one of the first, second and third sub-production times T1, T2 and T3. In an embodiment, the semiconductor device 10 may be produced by bonding the already produced modules (e.g., the first semiconductor device module 100, the second semiconductor device module 200, and the third semiconductor device module 300) to each other in a bonding process. In this regard, the second sub-production time T2 is the greatest, the production time to produce the semiconductor device 10 may be larger by at most 2 to 3 hours than the second production time T2. Thus, the cycle time of the semiconductor device 10 manufactured using the parallel manufacturing scheme is smaller than that of the semiconductor device 10 manufactured using the continuous manufacturing process. In other words, the production efficiency or the cost-effectiveness of producing the semiconductor device 10 may be improved. Additionally, the manufacturing resources, such as the semiconductor production apparatuses used to produce the device, may be utilized more efficiently.

Generally, in order for a semiconductor device to have optimal functionality and performance, elements in the semiconductor device are required to be exposed to a certain degree of temperature for a certain amount of time during the manufacturing process thereof. A first, second and third maximum temperatures may be highest temperatures to which the elements in the first, second and third semiconductor device modules 100, 200 and 300 may be subjected during their sub-manufacturing processes respectively. For example, it may be assumed that the second highest temperature is higher than the first highest temperature. In the continuous manufacturing process scheme, the first semiconductor device module 100 may be formed first, and subsequently, the second semiconductor device module 200 may be formed on the first semiconductor device module 100. In this case, during the sub-manufacturing process of the second semiconductor device module 200, the thermal budget (i.e., the certain degree of temperature for the certain amount of time) required to the second semiconductor device module 200 may be also applied to the first semiconductor device module 100. The second highest temperature, which is higher than the first highest temperature, may in a deteriorating way affect the functionality and performance of the first semiconductor device module 100 as a part of the semiconductor device 10. As a result, the portion included in the second semiconductor device module 200 cannot exhibit optimal performance.

However, when the first semiconductor device module 100 and the second semiconductor device module 200 are formed in the parallel manufacturing scheme, the first semiconductor device module 100 and the second semiconductor device module 200 may be respectively formed by the different sub-manufacturing process having the different highest temperatures so as to maintain optimal process conditions for both the first semiconductor device module 100 and the second semiconductor device module 200. Thus, the performance of the semiconductor device 10 including the first semiconductor device module 100 and the second semiconductor device module 200 may not be affected in a deteriorating way.

Hereinafter, a method for forming the first semiconductor device module 100 is briefly described.

Referring to FIG. 2 and FIG. 20, the logic transistor 110 may be formed on the first substrate 105 in S101.

The peripheral contact plug 111, the peripheral wiring line 112, and the peripheral wiring structure 100CWS connected to the logic transistor 110 may be formed.

The first bonding pad 101 connected to the logic transistor 110 may be formed such that a first semiconductor device module substrate (i.e., a plurality of the first semiconductor device modules in the form of a wafer) may be formed in S102. The first semiconductor device module substrate may include the logic transistor 110, the peripheral wiring line 112, the peripheral wiring structure 100CWS, and the first bonding pad 101.

Subsequently, the first semiconductor device module substrate may be tested in S103. The first semiconductor device module substrate may be tested such that characteristics of the first semiconductor device module substrate may be examined. If the first semiconductor device module substrate as tested is defective, a cause analysis may be conducted to determine the cause of the defect. Based on the analyzing result, the sub-manufacturing process that forms the first semiconductor device module substrate may be refined and adjusted for the subsequent production of the first semiconductor device module substrate.

Subsequently, the first semiconductor device module substrate may be diced in S104. Thus, the first semiconductor device module substrate may be separated such that a plurality of first semiconductor device modules 100 are formed.

When the semiconductor device 10 is manufactured according to a continuous manufacturing scheme, the characteristics of the semiconductor device 10 may be inspected at an end of the manufacturing process. If the semiconductor device 10 is defective, it takes a lot of time to determine at which manufacturing step the defect occurred. However, when the semiconductor device 10 is formed according to a parallel manufacturing scheme, the characteristics of the first semiconductor device module 100 are inspected during the process for forming the first semiconductor device module 100. In other words, the cause of the defect of the first semiconductor device module 100 may be more easily identified, and the time required to find the cause of the defect is reduced. Therefore, the production efficiency of the semiconductor device 10 may be increased.

Hereinafter, a method for forming the second semiconductor device module 200 is described.

Referring to FIG. 21 and FIG. 22, the memory cell array 210 may be formed on the second substrate 205 in S201.

The memory cell array 210 may be formed within the second module insulating film 220. For example, a portion of the second module insulating film 220 may be formed before the memory cell array 210 is entirely formed.

Although not shown, while the memory cell array 210 is being formed, the buffer conductive pattern (201PLG_BF in FIG. 8) may be formed.

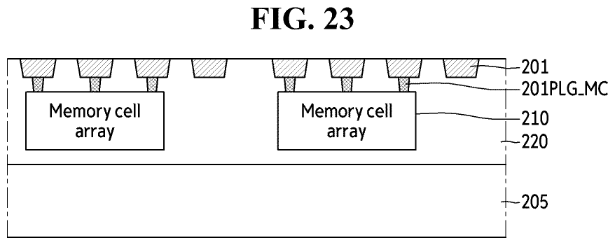

Referring to FIG. 21 and FIG. 23, the second lower bonding pad 201 connected to the memory cell array 210 may be formed in S202.

A portion of the second lower bonding pad 201 may be connected to the memory cell array 210, and the remainder of the second lower bonding pad 201 may not be connected to the memory cell array 210.

Although not shown, in one example, the bonding pad connection plug 201PLG_BP may be formed in the second module insulating film 220 before forming the second lower bonding pad 201. In another example, when the buffer conductive pattern (201PLG_BF in FIG. 8) is disposed within the second module insulating film 220, the lower bonding connection plug 201PLG_1 may be formed within the second module insulating film 220.

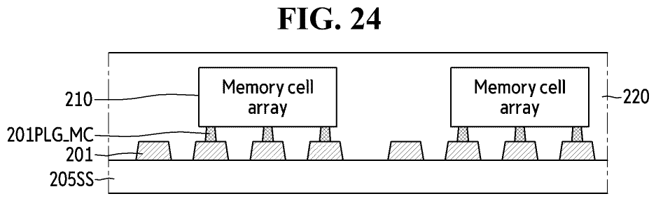

Referring to FIG. 21 and FIG. 24, the second substrate 205 on which the memory cell array 210 and the second lower bonding pad 201 have been formed may be attached to a first supporting substrate 205SS, and then, at least portion of the second substrate 205 may be removed in S203.

The second lower bonding pad 201 may face the first supporting substrate 205SS. In a semiconductor device manufacturing method according to some embodiments, after the second substrate 205 is attached to the first supporting substrate 205SS, the second substrate 205 may be removed entirely.

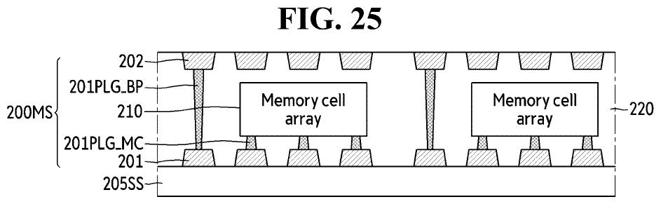

Referring to FIG. 21 and FIG. 25, the second upper bonding pad 202 may be formed within the second module insulating film 220 such that the second semiconductor device module substrate 200MS (i.e., a plurality of the second semiconductor device modules in the form of a wafer) may be formed in S204.

For example, the bonding pad connection plug 201PLG_BP may be formed within the second module insulating film 220. The bonding pad connection plug 201PLG_BP is connected to the second lower bonding pad 201. Subsequently, the second upper bonding pad 202 may be formed. A portion of the second upper bonding pad 202 is connected to the bonding pad connection plug 201PLG_BP.

The second semiconductor device module substrate 200MS may include the memory cell array 210, the second lower bonding pad 201, the second upper bonding pad 202, and the bonding pad connection plug 201PLG_BP.

Subsequently, the second semiconductor device module substrate 200MS may be tested in S205. The second semiconductor device module substrate 200MS may be tested such that the characteristics of the second semiconductor device module substrate 200MS may be examined. For example, testing the second semiconductor device module substrate 200MS may include testing the characteristics of the memory cell array 210.

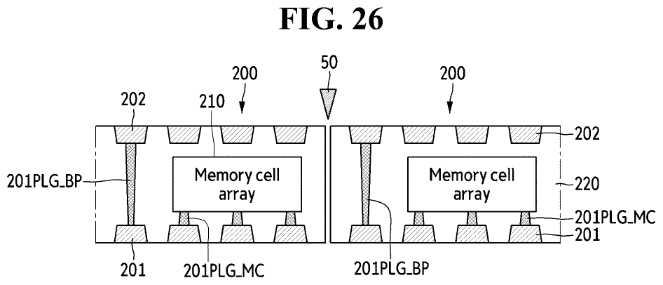

Referring to FIG. 21 and FIG. 26, the second semiconductor device module substrate 200MS may be diced on a module basis in S206.

In the dicing process S206, the second semiconductor device module substrate 200MS may be divided into modules as indicated by the reference number 50. Thus, the second semiconductor device module substrate 200MS may be separated such that a plurality of second semiconductor device modules 200 are formed.

In one example, the second semiconductor device module 200 may be formed, and, subsequently, the first supporting substrate 205SS may be removed. In another example, before the second semiconductor device module 200 is formed, the first supporting substrate 205SS may be removed.

Hereinafter, a method for forming the third semiconductor device module 300 is described.

Referring to FIG. 27 and FIG. 29, the wiring structure 300CWS may be formed on the third substrate 305 in S301.

The wiring structure 300CWS may be formed within the third module insulating film 320. In one example, the wiring connection line and wiring connection via included in the wiring structure 300CWS may be formed simultaneously using a dual damascene scheme. In another example, each of the wiring connection line and wiring connection via included in the wiring structure 300CWS may be formed separately using a single damascene scheme. In still another example, the wiring connection line and wiring connection via included in the wiring structure 300CWS may be formed using a combination of a damascene scheme and a subtractive etch scheme.

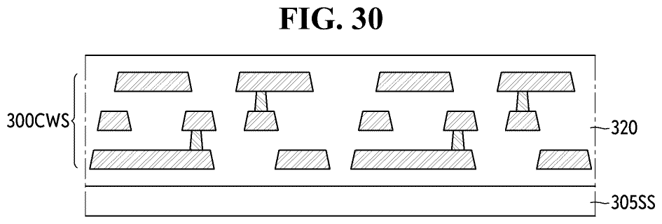

Referring to FIG. 27 and FIG. 30, the third substrate 305 may be attached to a second supporting substrate 305SS, and, subsequently, the third substrate 305 may be removed in S302.

In a state in which the wiring structure 300CWS has been formed on the third substrate 305, the third substrate 305 may be attached to the second supporting substrate 305SS.

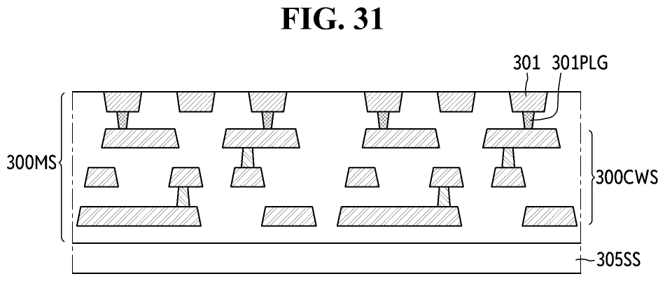

Referring to FIG. 27 and FIG. 31, the third bonding pad 301 may be formed within the third module insulating film 320 such that a third semiconductor device module substrate 300MS may be formed.

For example, the third bonding pad plug 301PLG may be formed within the third module insulating film 320. The third bonding pad plug 301PLG is connected to the wiring structure 300CWS. Subsequently, the third bonding pad 301 may be formed on the third bonding pad plug 301PLG.

The third semiconductor device module substrate 300MS (i.e., a plurality of the third semiconductor device modules in the form of a wafer) may include the wiring structure 300CWS, the third bonding pad 301, and the third bonding pad plug 301PLG.

Subsequently, the third semiconductor device module substrate 300MS may be tested in S304. The third semiconductor device module substrate 300MS may be tested such that the characteristics of the third semiconductor device module substrate 300MS may be examined. For example, testing the third semiconductor device module substrate 300MS may include testing connection characteristics of the wiring structure 300CWS.

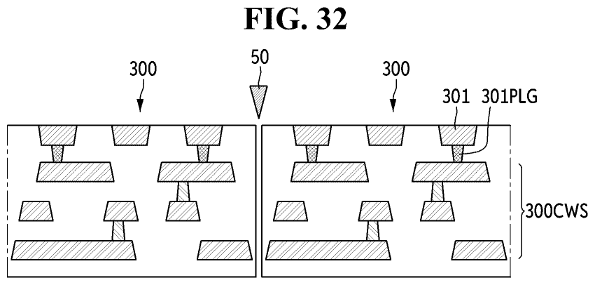

Referring to FIG. 27 and FIG. 32, the third semiconductor device module substrate 300MS may be diced on a module basis in S305. In the dicing as indicated by the reference number 50, the third semiconductor device module substrate 300MS may be divided into modules. Thus, the third semiconductor device module substrate may be separated such that a plurality of third semiconductor device modules 300 are formed.

In one example, after the third semiconductor device module 300 has been formed, the second supporting substrate 305SS may be removed. In another example, before the third semiconductor device module 300 is formed, the second supporting substrate 305SS may be removed.

Although not shown, the contact pad 15 may be formed on the third semiconductor device module substrate 300MS.

Hereinafter, another method for forming the third semiconductor device module 300 is described.

Referring to FIGS. 28 to 30, before attaching the third substrate 305 to the second supporting substrate 305SS, the third bonding pad 301 connected to the wiring structure 300CWS may be formed within the third module insulating film 320 (in S303 in FIG. 28).

Thus, the third semiconductor device module substrate 300MS may be formed on the third substrate 305.

Subsequently, the third semiconductor device module substrate 300MS may be tested in S304 in FIG. 28.

Subsequently, the third substrate 305 on which the third semiconductor device module substrate 300MS has been formed may be attached to the second supporting substrate 305SS, and then the third substrate 305 may be removed (in S302 in FIG. 28).

After removing the third substrate 305, the third semiconductor device module substrate 300MS may be diced on a module basis (in S305 in FIG. 28).

With respect to FIGS. 19, 20, 21 and 27, the first to third semiconductor device modules are described as being in the form of divided modules before the bonding process in S10. However, in some embodiments, the first to third semiconductor device modules may be bonded together in the form of wafers, each of which includes the first to third semiconductor device modules, respectively. Subsequently, the bonded wafers may be divided into the plurality of the semiconductor devices 10. The test process S20 may be performed before or after the dividing process.

In some embodiments, the test processes S103, S205 and S304 may be performed after the dicing process S104, S206, S305, respectively.

In some embodiments, when the first to third semiconductor device modules are bonded together into the plurality of the semiconductor devices 10, at least one of the first to third semicon/≥ductor device modules may be in the form of wafer. For example, divided third and second semiconductor device modules may be bonded onto a wafer including the first semiconductor device modules, and then the resultant bonded structure may be divided into the plurality of the semiconductor devices 10. each of which includes the first to third semiconductor device modules, respectively. Subsequently, the bonded wafers may be finally divided into a plurality of the semiconductor devices 10 each including the first to third semiconductor device modules. The test process S20 may be performed before or after the final dividing process.

For another example, a wafer including first semiconductor device modules and a wafer including second semiconductor device modules may be bonded to form a bonded composite wafer. Subsequently, divided first semiconductor device modules may be bonded onto the bonded composite wafer. The resultant structure may be finally divided into the plurality of the semiconductor devices 10 each including the first to third semiconductor device modules. The test process S20 may be performed before or after the final dividing process.

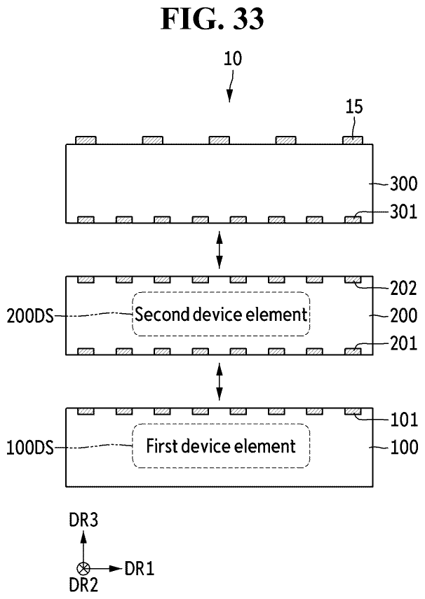

Referring to FIG. 19 and FIG. 33, the first semiconductor device module 100, the second semiconductor device module 200, and the third semiconductor device module 300 may be bonded together in S10.

The first bonding pad 101 and the second lower bonding pad 201 may be connected to each other such that the first semiconductor device module 100 and the second semiconductor device module 200 may be bonded to each other. The third bonding pad 301 and the second upper bonding pad 202 may be connected to each other such that the second semiconductor device module 200 and the third semiconductor device module 300 may be bonded to each other.

After bonding the first semiconductor device module 100, the second semiconductor device module 200, and the third semiconductor device module 300 to each other, a combination of the first semiconductor device module 100, the second semiconductor device module 200 and the third semiconductor device module 300 may be tested in S20.

In other words, overall characteristics of the semiconductor device (10 in FIG. 1) may be inspected.

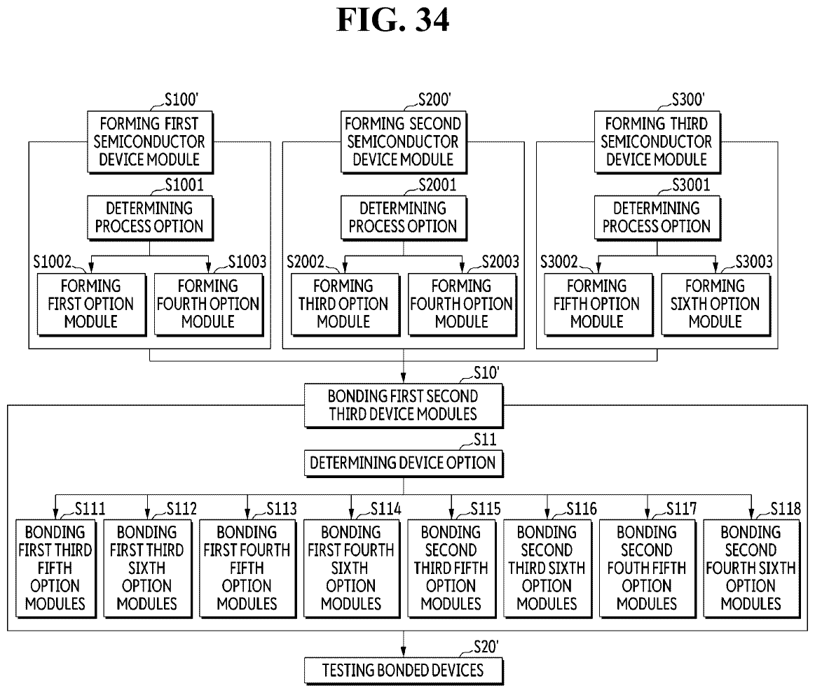

FIG. 34 is a diagram for illustrating a semiconductor device manufacturing method according to some embodiments.

Referring to FIG. 34, the first semiconductor device module 100 in FIG. 1 may be formed in S100′. The second semiconductor device module 200 in FIG. 1 may be formed in S200′. The third semiconductor device module 300 in FIG. 1 may be formed in S300′. The process stages S100′, S200′ and S300′ may correspond to the process stages S100, S200 and S300 in FIG. 19, respectively. Accordingly, contents duplicate with what have been described above using FIGS. 1 to 33 are briefly described or descriptions thereof are omitted.

The first semiconductor device module 100, the second semiconductor device module 200, and the third semiconductor device module 300 may be produced into a plurality of optional products with the same function but with different performance and different manufacturing costs, respectively. For example, The process stage S100′ may include a stage S1001, in which one or more options among a first and second option modules is selected. Similarly, the process stage S200′ may include a stage S2001, in which one or more options among a third and fourth option modules is selected, and the process stage S300′ may include a stage S3001, in which one or more options is selected among a fifth and sixth option modules. The different options may refer to different types of modules (e.g., including different types of transistors, different types of plugs, etc.).

The first and second option modules may be structurally different from each other, may be produced by different processes. For example, based on the determination, the process to produce the first semiconductor device module 100 may be selected. For example, the first option module may include a planar type transistor (shown in FIG. 2) as a logic transistor 110, and the second option module may include a fin-type transistor (shown in FIG. 3) as a logic transistor 110. Accordingly, the second option module may operate such that the semiconductor device 10 has higher performance with higher manufacturing cost than the first option module, when they are bonded to the same kind of the second and third semiconductor device modules.

Similarly, the third and fourth option modules may be structurally different from each other, may be produced by different processes, and the fifth and sixth option modules may be structurally different from each other, may be produced by different processes. For example, the processes to produce the second and third semiconductor device modules 200 and 300 may be selected to produce a plurality of option modules. For example, the third option module may include a capacitor dielectric film 210CI (shown in FIG. 10) formed of a ferroelectric material, and the fourth option module may include a capacitor dielectric film 210CI formed of a combination of a ferroelectric material and an antiferroelectric material. For example, the fifth option module may include wiring connection lines 315, 316, and 317 (shown in FIG. 15) formed of a relatively high resistance material with low manufacturing cost, while the sixth option module may include connection lines 315, 316, and 317 formed of a relatively low resistance material with high manufacturing cost.

The first semiconductor device module 100, the second semiconductor device module 200, and the third semiconductor device module 300 may be bonded together in S10′. The process stage S10′ may correspond to the process stage S10 in FIG. 19. Accordingly, contents duplicate with what have been described above using FIGS. 1 to 33 are briefly described or descriptions thereof are omitted.

The semiconductor devices 10 may be produced into a plurality of optional products with the same function but with different performance and different manufacturing cost. The semiconductor devices 10 may be produced in various kinds of combinations of the option modules as shown in S111 to S118. For example, the process stage S10′ may include a stage S11, in which one or more options among the options indicated in S111 to S118 is determined. Based on the determination, one or more types of the semiconductor devices 10 may be produced. Accordingly, it will be possible to produce a wide range of optional products configured to perform the same function in an efficient way and in a short time, thereby satisfying the diverse needs of customers and the market.

Though the first and second option modules may be structurally different from each other, at least a portion of structural features may be the same as each other. For example, the first bonding pads 101 of the first and second option modules may have the same structural feature (e.g., position in a plan view, number and/or size in a plan view) as each other. As a result, the first and second option modules may be capable to be compatibly bonded with ensured quality to a second semiconductor device module.

Similarly, though the third and fourth option modules may be structurally different from each other, at least a portion of structural features may be the same as each other. For example, the second lower and upper bonding pads 201 and 202 of the third and fourth option modules may have the same structural feature (e.g., position in a plan view, number and/or size in a plan view) as each other. As a result, the third and fourth option modules may be capable to be compatibly bonded with ensured quality to a first semiconductor device module and a second semiconductor device module.

Still similarly, though the fifth and sixth option modules may be structurally different from each other, at least a portion of structural features may be the same as each other. For example, the third bonding pads 302 of the third and fourth option modules may have the same structural feature (e.g., position in a plan view, number and/or size in a plan view) as each other. As a result, the fifth and sixth option modules may be capable to be compatibly bonded with ensured quality to a second semiconductor device module.

Accordingly, any options as indicated in S111 to S118 may have ensured connection quality to outside of the semiconductor device 10.

The first semiconductor device module 100 may be produced so as to have various characteristics (e.g., reliability or processing speed). Likewise, the second semiconductor device module 200 may be produced to include the memory cell array (210 in FIGS. 6 to 8) with various performances. Depending on what wiring material is used or what manufacturing method is used, the characteristics of the wiring structure (300CWS in FIG. 13, FIG. 15, and FIG. 16) included in the third semiconductor device module 300 may vary.

When the semiconductor device including the logic transistor, the memory cell, and the wiring structure is produced using the continuous manufacturing scheme, the semiconductor devices with specific characteristics have no choice but to be mass-produced. Additionally, it may take a lot of time for the semiconductor device to be manufactured.

However, according to the present invention, each of the portions including the logic transistor, the portion including the memory cell, and the portion including the wiring structure is produced in a modular form. Thus, the semiconductor device modules with desired characteristics may be bonded to each other, such that the manufacturing time of the semiconductor device may be shortened. Additionally, the semiconductor device may be produced by combining the semiconductor device modules with various characteristics with each other. Thus, many types of products may be produced in small quantities. In addition, since the portion including the logic transistor, the portion including the memory cell, and the portion including the wiring structure are produced separately, inventory management may be facilitated.

Although embodiments of the present invention have been described with reference to the accompanying drawings, the present invention is not limited to the above embodiments, but may be implemented in various different forms. A person skilled in the art may appreciate that the present invention may be practiced in other concrete forms without changing the technical spirit or essential characteristics of the present invention. Therefore, it should be appreciated that the embodiments as described above are not restrictive but illustrative in all respects.

1. A semiconductor device comprising:
a first semiconductor device module including:
a first lower bonding pad;
a second lower bonding pad;
first upper bonding pads; and
a memory cell disposed at a height level higher than a height level of each of the first and second lower bonding pads and lower than a height level of the first upper bonding pads;
a second semiconductor device module including second bonding pads and a transistor electrically connected to at least one of the second bonding pads; and
a third semiconductor device module including third bonding pads,
wherein the first upper bonding pads are spaced apart from the first and second lower bonding pads in a first direction,
wherein the first lower bonding pad contacts at least one of the second bonding pads,
wherein at least one of the third bonding pads contacts at least one of the first upper bonding pads, and
wherein the first semiconductor device module includes a bonding pad connection plug directly electrically connecting the first lower bonding pad and at least one of the first upper bonding pads to each other.

2. The semiconductor device of claim 1, wherein the memory cell includes a bit-line extending in a second direction and a word-line extending in a third direction,
wherein the second lower bonding pad is one of a plurality of second lower bonding pads
wherein at least one of the word-line and the bit-line is electrically connected to a corresponding one of the second lower bonding pads.

3. The semiconductor device of claim 2, wherein within the first semiconductor device module, the bonding pad connection plug is electrically isolated from the word-line and the bit-line.

4. The semiconductor device of claim 1, wherein the bonding pad connection plug is in contact with the first lower bonding pad and at least one of the first upper bonding pads.

5. The semiconductor device of claim 1, wherein the bonding pad connection plug includes an upper bonding connection plug, a lower bonding connection plug, and a buffer conductive pattern disposed between the upper bonding connection plug and the lower bonding connection plug.

6. The semiconductor device of claim 1, wherein the third semiconductor device module includes a plurality of wiring lines spaced apart from each other in the first direction,
wherein the third bonding pads are electrically connected to the plurality of wiring lines, and
wherein the third semiconductor device module does not include a memory cell or a logic transistor.

7. The semiconductor device of claim 1, wherein the first lower bonding pad is one of a plurality of first lower bonding pads that contact a first set of the second bonding pads in a one-to-one manner, and the second lower bonding pad is one of a plurality of second lower bonding pads that contact a second set of the second bonding pads in a one-to-one manner.

8. The semiconductor device of claim 1, wherein the first upper bonding pads correspond to the third bonding pads in a one-to-one manner.

9. The semiconductor device of claim 1, wherein the first lower bonding pad has a shape such that a width of the first lower bonding pad increases as it moves away from the third semiconductor device module, and
wherein each of the first upper bonding pads has a shape such that a width of each of the first upper bonding pads increases as it moves away from the second semiconductor device module.

10. The semiconductor device of claim 1, wherein the memory cell includes a data storage pattern.

11. The semiconductor device of claim 1, further comprising a contact pad disposed on the third semiconductor device module,
wherein the third semiconductor device module includes a plurality of wiring lines spaced apart from each other in the first direction, and
wherein the contact pad is connected to at least one of the wiring lines.

12. A semiconductor device comprising:
a first semiconductor device module including:
first lower bonding pads;
second lower bonding pads;
first upper bonding pads; and
a first semiconductor device element disposed at a height level higher than respective height levels of the first and second lower bonding pads and lower than a height level of the first upper bonding pads;
a second semiconductor device module including second bonding pads and a second semiconductor device element; and
a third semiconductor device module including third bonding pads,
wherein the first upper bonding pads are spaced apart from the first and second lower bonding pads in a first direction,
wherein each first lower bonding pad contacts at least one of the second bonding pads,
wherein at least one of the third bonding pads contacts at least one of the first upper bonding pads, and
wherein one of the first and second semiconductor device elements includes a peripheral circuit, and the other thereof includes a memory cell.

13. The semiconductor device of claim 12, wherein the first semiconductor device element includes the memory cell,
wherein the second semiconductor device element includes the peripheral circuit,
wherein the third semiconductor device module does not include a memory cell or a logic transistor.

14. A method for manufacturing a semiconductor device, the method comprising:
forming a first semiconductor device module, wherein the first semiconductor device module includes a first lower bonding pad and first upper bonding pads spaced apart from each other in a first direction, a second lower bonding pad and a memory cell disposed at a height level higher than respective height levels of the first and second lower bonding pads and lower than a height level of the first upper bonding pads;
forming a second semiconductor device module, wherein the second semiconductor device module includes second bonding pads and a transistor electrically connected to at least one of the second bonding pads;
forming a third semiconductor device module, wherein the third semiconductor device module includes third bonding pads and wiring lines, wherein at least one of the wiring lines is connected to at least one of the third bonding pads;
connecting at least one of the second bonding pads and the first lower bonding pad to each other to bond the first semiconductor device module and the second semiconductor device module to each other; and
connecting the third bonding pads and the first upper bonding pads to each other in a one-to-one manner to bond the first semiconductor device module and the third semiconductor device module to each other,
wherein the first semiconductor device module, the second semiconductor device module, and the third semiconductor device module are formed in a parallel manufacturing scheme.

15. The method of claim 14, wherein the forming of the first semiconductor device module includes forming a bonding pad connection plug connecting the first lower bonding pad and at least one of the first upper bonding pads to each other.

16. The method of claim 14, wherein the forming of the first semiconductor device module includes:
forming a memory cell on a substrate;
forming the first upper bonding pads on the memory cell;
attaching the substrate, on which the first lower bonding pad has been formed to, to a supporting substrate;
after the attaching, removing at least portion of the substrate;
after the removing the at least a portion of the substrate, forming the first upper bonding pads to form a first semiconductor device module substrate; and
dicing the first semiconductor device module substrate to form the first semiconductor device module.

17. The method of claim 14, wherein the forming of the first semiconductor device module includes testing characteristics of the memory cell.

18. The method of claim 17, further comprising testing characteristics of a bonded structure of the first semiconductor device module, the second semiconductor device module, and the third semiconductor device module,
wherein the bonded structure is produced by the connecting at least one of the second bonding pads and the first lower bonding pad to each other and by the connecting the third bonding pads and the first upper bonding pads to each other.

19. The method of claim 14, wherein the forming of the third semiconductor device module includes:
forming the wiring lines on a substrate;
forming the third bonding pads on the wiring lines to form a third semiconductor device module substrate;
attaching the substrate, on which the wiring lines and the third bonding pads have been formed, to a supporting substrate;
removing the substrate after the attaching the substrate; and
after removing the substrate, dicing the third semiconductor device module substrate to form the third semiconductor device module.

20. The method of claim 14, wherein the forming of the third semiconductor device module includes:
forming the wiring lines on a substrate;
attaching the substrate, on which the wiring lines have been formed to a supporting substrate;
removing the substrate after the attaching the substrate;
after removing the substrate, forming the third bonding pads to form a third semiconductor device module substrate; and
dicing the third semiconductor device module substrate to form the third semiconductor device module.

21-26. (canceled)
